(19) United States
(12) Patent Application Publication
(10) Pub. No.: US 2026/0142122 A1
(43) Pub. Date: May 21, 2026

(54) PARTICLE BEAM SYSTEM AND METHOD

(71) Applicant: TEL Manufacturing and Engineering of America, Inc., Chaska, MN (US)

(72) Inventors: Hongyu Henry Yue, Andover, MA (US); Wei-Jung Lai, Arlington, MA (US); Steven Caliendo, Ashby, MA (US); Kenneth Regan, Beverly, MA (US)

(21) Appl. No.: 18/951,091

(22) Filed: Nov. 18, 2024

(51) Int. Cl. H01J 37/304; H01J 37/20; H01J 37/305

(52) U.S. Cl. CPC H01J 37/3045; H01J 37/20; H01J 37/3053; H01J 2237/202; H01J 2237/30483

(57) ABSTRACT

A method includes: determining a plurality of paths on a surface of a wafer; determining an overscan region for the wafer; (a) setting an etch rate of a particle beam; (b) scanning the particle beam along a first path of the plurality of paths; (c) monitoring a location of the particle beam along the first path; (d) in response to determining that the particle beam is located at an outer edge of the overscan region: turning on a reduced trim mode, where turning on the reduced trim mode comprises reducing the etch rate of the particle beam; decelerating the wafer to zero scanning speed; accelerating the wafer until the particle beam is located at an outer edge of the overscan region; and turning off the reduced trim mode; and repeating (a)-(d) for each subsequent path of the plurality of paths until all paths have been scanned.

### TECHNICAL FIELD

The present disclosure relates generally to systems and methods for processing a substrate and, in particular embodiments, to a particle beam system and method.

### BACKGROUND

Particle beam systems have been widely utilized in various fields, including semiconductor manufacturing, materials science, and medical applications. These systems employ beams of charged or neutral particles to modify, analyze, or treat target materials with high precision and control. Conventional particle beam systems typically consist of several components: a source for generating particles, an extraction system, an acceleration system, focusing and steering elements, and a target chamber. While effective for many applications, existing systems face challenges in maintaining beam stability, providing ion species versatility, preventing target contamination, improving energy efficiency, and reducing size and complexity.

### SUMMARY

In accordance with an embodiment of the present disclosure, an apparatus includes: a process chamber configured to hold a wafer; a nozzle within the process chamber, where the nozzle is configured to provide a particle beam impacting the wafer; and a controller operably coupled to the process chamber, where the controller is configured to: determine a plurality of paths on a surface of the wafer; determine an overscan region for the wafer; (a) set an etch rate of the particle beam; (b) scan the particle beam along a first path of the plurality of paths; (c) monitor a location of the particle beam along the first path; (d) in response to determining that the particle beam is located at an outer edge of the overscan region: turn on a reduced trim mode, where turning on the reduced trim mode comprises reducing the etch rate of the particle beam; decelerate the wafer to zero scanning speed; accelerate the wafer until the particle beam is located at an outer edge of the overscan region; and turn off the reduced trim mode; and repeat (a)-(d) for each subsequent path of the plurality of paths until all paths have been scanned.

In accordance with another embodiment of the present disclosure, a device operably coupled to a process chamber of a particle beam apparatus, the device includes: a processor; a non-transitory computer-readable medium storing software instructions that, when executed by the processor, causes the processor to: determine a plurality of paths on a surface of a wafer; determine an overscan region for the wafer; (a) set an etch rate of a particle beam; (b) scan the particle beam along a first path of the plurality of paths; (c) monitor a location of the particle beam along the first path; (d) in response to determining that the particle beam is located at an outer edge of the overscan region: turn on a reduced trim mode, where turning on the reduced trim mode comprises reducing the etch rate of the particle beam; decelerate the wafer to zero scanning speed; accelerate the wafer until the particle beam is located at an outer edge of the overscan region; and turn off the reduced trim mode; and repeat (a)-(d) for each subsequent path of the plurality of paths until all paths have been scanned.

In accordance with yet another embodiment of the present disclosure, a method includes: determining a plurality of paths on a surface of a wafer; determining an overscan region for the wafer; (a) setting an etch rate of a particle beam; (b) scanning the particle beam along a first path of the plurality of paths; (c) monitoring a location of the particle beam along the first path; (d) in response to determining that the particle beam is located at an outer edge of the overscan region: turning on a reduced trim mode, where turning on the reduced trim mode comprises reducing the etch rate of the particle beam; decelerating the wafer to zero scanning speed; accelerating the wafer until the particle beam is located at an outer edge of the overscan region; and turning off the reduced trim mode; and repeating (a)-(d) for each subsequent path of the plurality of paths until all paths have been scanned.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a schematic view of a particle beam apparatus in accordance with various embodiments;

FIG. 2 is a schematic view of a particle beam process in accordance with various embodiments; and

FIGS. 3A-3C illustrate a flow diagram of a particle beam method in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

The present disclosure describes various embodiments of a particle beam system and method that address various challenges faced by conventional particle beam systems. The particle beam method that is performed by particle beam system may be an etch process. In some embodiments, the method may begin by determining a plurality of paths on a surface of a wafer and an overscan region for the wafer. Initially, a scanning speed and duty cycle of a particle beam are set to achieve a desired etch rate. The particle beam is then scanned along a first path of the plurality of paths, during which the scanning speed and duty cycle may be altered, thereby altering the etch rate. The location of the particle beam along the path may be continuously monitored. Upon reaching an outer edge of the overscan region, a reduced trim mode is turned on. The reduced trim mode may include reducing the etch rate by altering the duty cycle of the particle beam or by turning of the particle beam off, decelerating the particle beam for a first time period, then accelerating the particle beam for a second time period before turning off the reduced trim mode. This process is repeated for each subsequent path. For each new path, the scanning speed and duty cycle may be reset, and then may be altered during scanning. The beam's location is monitored, and the reduced trim mode turn-off, particle beam deceleration, particle beam acceleration, and reduced trim mode turn-on sequence may be repeated at the overscan region. This entire process may continue until all predetermined paths on the wafer surface have been scanned. This method allows for controlling the particle beam across the wafer surface, accommodating speed and duty cycle variations while managing the beam's behavior at overscan region boundaries.

Various embodiments of the disclosed apparatus and method ensure that the entire wafer receives controlled particle beam treatment, with the flexibility to adjust beam parameters (such as scanning speed, duty cycle, pulse frequency, and etch rate) for each path and during scanning. The management of the beam at the outer boundary of the overscan region may prevent overexposure (e.g., overetch) at the edge of the wafer and allow for seamless transitions between paths. This approach may result in uniform and accurate particle beam treatment across the entire wafer surface that is desired for many advanced semiconductor manufacturing processes. Furthermore, by using the reduced trim mode, the area of the overscan region may be reduced, lifetime of parts of the particle beam apparatus that would be otherwise exposed to the particle beam in the overscan region may be improved, and amount of particles generated by to the particle beam may be reduced. By reducing the area of the overscan region, time spent by the particle beam in the overscan region may be reduced and a wafer-per-hour yield of the particle beam apparatus may be improved.

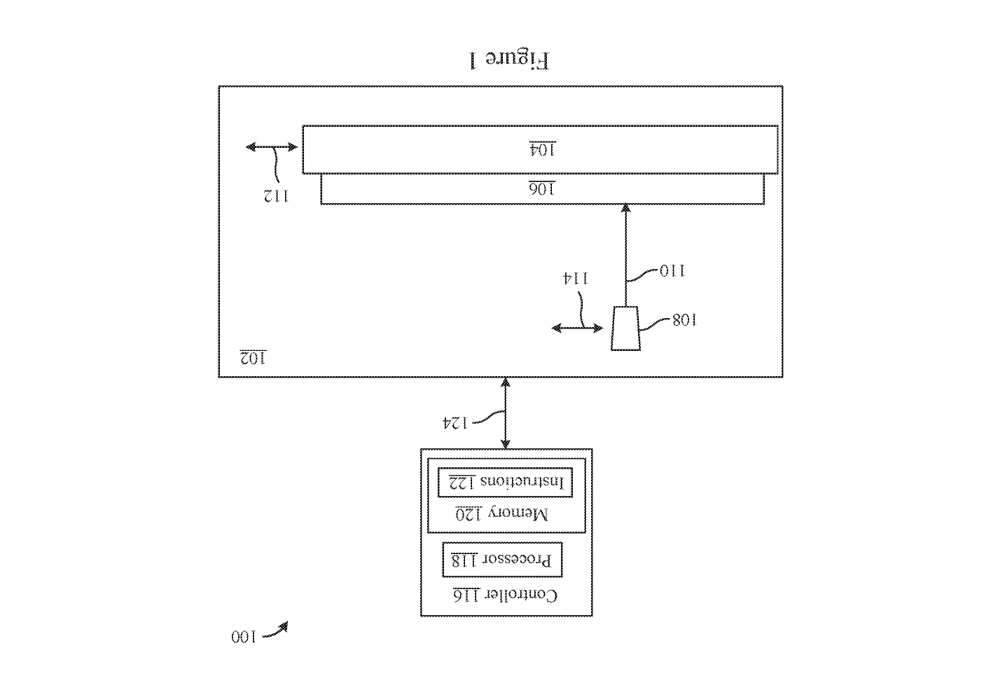

FIG. 1 is a schematic view of a particle beam apparatus 100 in accordance with various embodiments. The particle beam apparatus 100 may be configured to perform an etch process (also referred to as a trim process) on one or more wafers (e.g., wafer 106). The wafer 106 may comprise a substrate. The substrate may include MEMS devices, semiconductor devices, or semiconductor structures and may be formed in any suitable manner, including using any suitable combination of wet and/or dry deposition and etch techniques.

The substrate may comprise layers of semiconductors suitable for various microelectronics. In one or more embodiments, the substrate may be a silicon wafer. In certain embodiments, the substrate may comprise a silicon germanium wafer, silicon carbide wafer, gallium arsenide wafer, gallium nitride wafer, or other compound semiconductors. In other embodiments, the substrate may comprise heterogeneous layers such as silicon germanium on silicon, gallium nitride on silicon, silicon carbon on silicon, or layers of silicon on a silicon or SOI substrate. In other embodiments, the substrate may comprise a dielectric material, a glass, or the like.

In some embodiments, the wafer 106 may comprises a target layer over the substrate. The target layer may be patterned by an etch process performed by the particle beam apparatus 100. The target layer may comprise silicon, silicon oxide, silicon nitride, silicon carbon, lithium tantalite, lithium niobate, aluminum nitride, metal films (e.g., tungsten, molybdenum, gold, titanium, ruthenium, or the like), a combination thereof, or the like. The target layer may be a mask layer comprising a hard mask. The target layer may be deposited using suitable deposition processes. Suitable deposition processes may include a spin-on coating process, a chemical vapor deposition (CVD) process, an atomic layer deposition (ALD) process, plasma deposition processes (e.g., a plasma-enhanced CVD (PECVD) process, or a plasma-enhanced ALD (PEALD) process), and/or other deposition processes or combinations of processes.

In some embodiments, the particle beam apparatus 100 comprises a process chamber 102. The process chamber 102 may be a vacuum chamber. In such embodiments, the particle beam apparatus 100 may comprise one or more pumps (not shown) that are configured to maintain desired vacuum conditions within the process chamber 102. In some embodiments, the wafer 106 may be supported by a chuck 104. The chuck 104 may be a mechanical chuck comprising clamps, a vacuum chuck, an electrostatic chuck, or the like. The chuck 104 is configured to support the wafer 106 during a particle beam process (e.g., an etch process) performed by the particle beam apparatus 100.

In some embodiments, the particle beam apparatus 100 further comprises a nozzle 108. The nozzle 108 is configured to provide a particle beam 110 that impacts the wafer 106 during a particle beam process (e.g., an etch process). The particle beam 110 may be a continuous beam or a pulsed beam. The particle beam 110 may comprise charged particles, neutral particles, or combinations thereof. The neutral particles may comprise neutral atoms, neutral molecules, or neutral clusters. The charged particles may comprise ionized atoms, ionized molecules, or ionized clusters. In some embodiments, the particle beam 110 may comprise ionized or neutral clusters of NF₃, CF₄, CHF₃, N₂, O₂, Ar, combinations thereof, or the like. In some embodiments, the particle beam 110 may have a full width at half maximum (FWHM) in a range from 4 mm to 20 mm. The particle beam 110 may be also referred to as a gas cluster beam (GCB).

In some embodiments, the chuck 104 may be configured to move laterally with respect to the fixed particle beam 110 as indicated by an arrow 112 such that the particle beam 110 scans a surface of the wafer 106. In such embodiments, the chuck 104 may be coupled to a suitable motor. In other embodiments, the nozzle 108 may be configured to move laterally with respect to the fixed chuck 104 as indicated by an arrow 114 such that the particle beam 110 scans the surface of the wafer 106. In such embodiments, the nozzle 108 may be coupled to a suitable motor. In yet other embodiments, both the chuck 104 and the nozzle 108 may be configured to move laterally with different speeds such that the particle beam 110 scans the surface of the wafer 106. In some embodiments, the particle beam apparatus 100 may comprise an ionizer, an accelerator, beam filters and apertures that are disposed between the nozzle 108 and the chuck 104.

In some embodiments, the particle beam apparatus 100 may further comprise a controller 116. The controller 116 may be configured to send and/or receive signals 124 to and/or from various components of the particle beam apparatus 100 to control operations of the components of the particle beam apparatus 100 and to achieve the functions described herein. The controller 116 may be implemented in a wide variety of manners. For example, the controller 116 may be a computing device comprising a processor 118 operable coupled to a memory 120. The processor 118 may comprise one or more processors (e.g., microprocessor, microcontroller, central processing unit, etc.), programmable logic devices (e.g., complex programmable logic device (CPLD)), field programmable gate array (FPGA), etc.), and/or other programmable integrated circuits can be programmed with software or other programming instructions 122 to implement the functionality of the particle beam apparatus 100. In some embodiments, the controller 116 may generate a speed map comprising position-velocity-time (PVT) information, generate signals 124 based on the speed map and send the signals 124 to a motor of the chuck 104 or the nozzle 108.

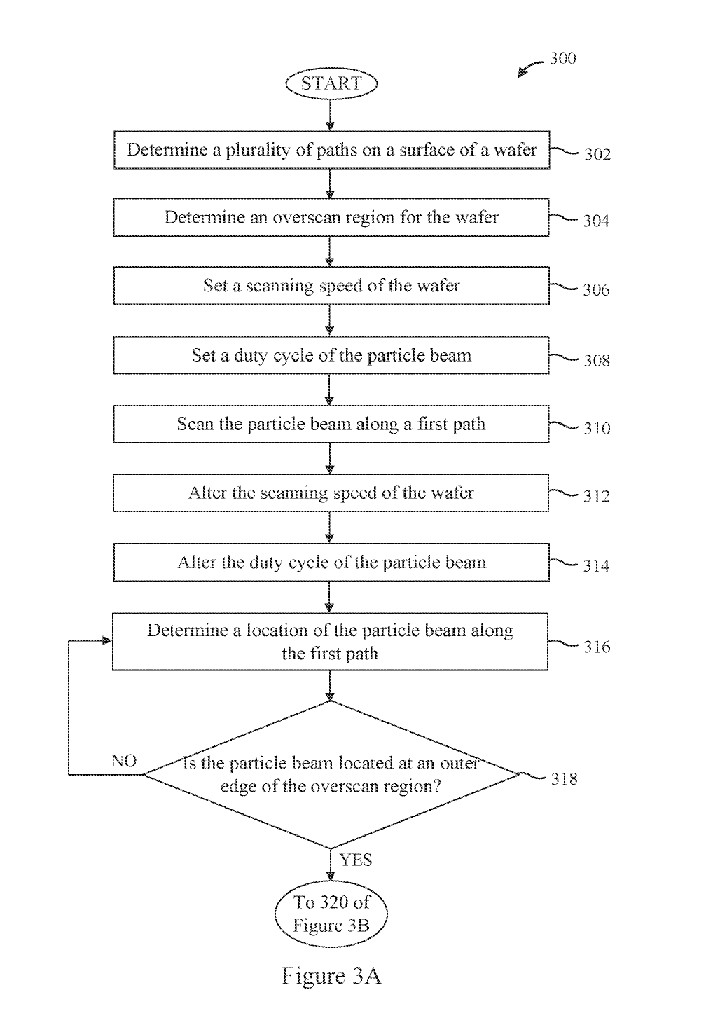

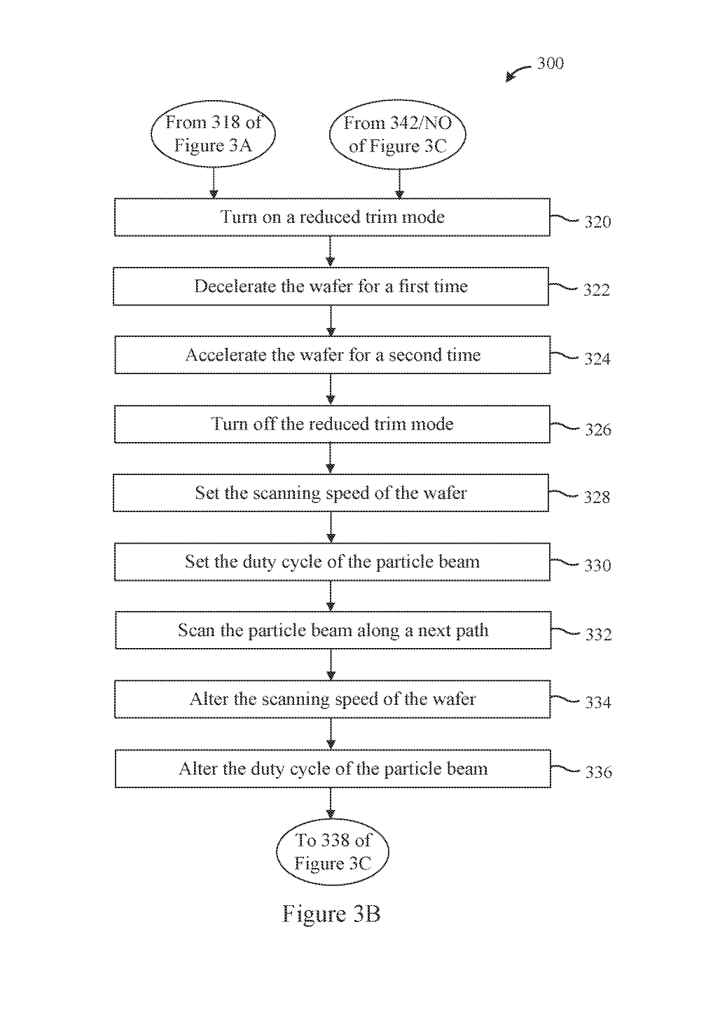

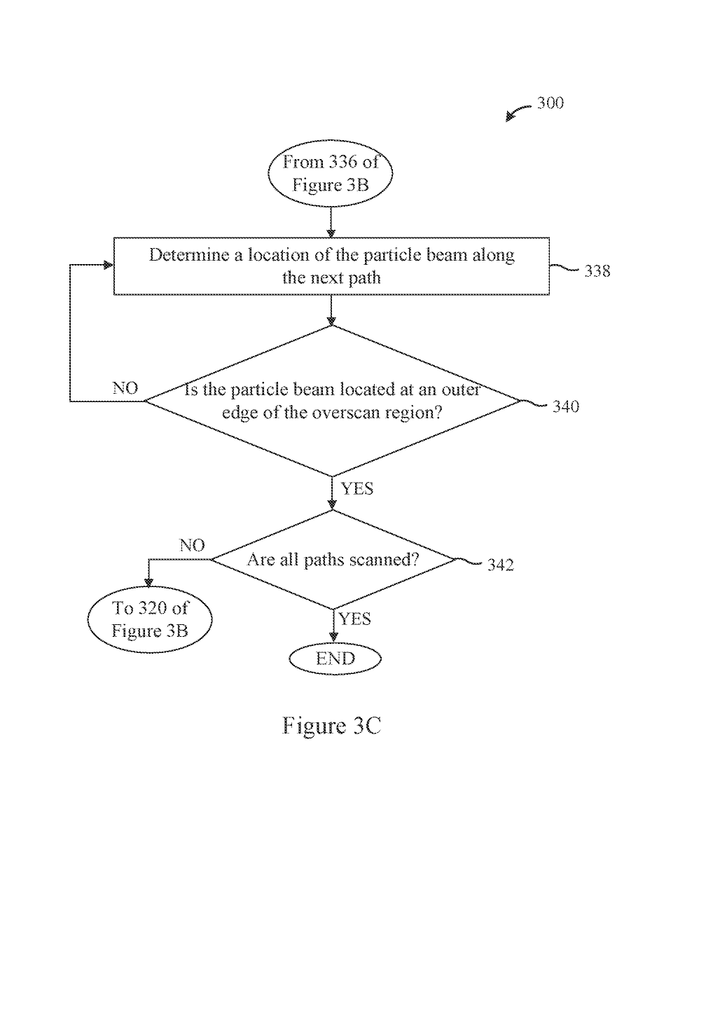

In some embodiments, the software or other programming instructions 122 can be stored in the memory 120. The memory 120 may comprise one or more non-transitory computer-readable mediums (e.g., memory storage devices, FLASH memory, DRAM memory, reprogrammable storage devices, hard drives, floppy disks, DVDs, CD-ROMs, etc.), and the software or other programming instructions 122, when executed by the processor 118, cause the processor 118 to perform the processes, functions, and/or capabilities described herein. In some embodiments, the particle beam apparatus 100 may be operated according to a method 300 described below with reference to FIGS. 3A-3C to perform a particle beam process (e.g., an etch process) on the wafer 106.

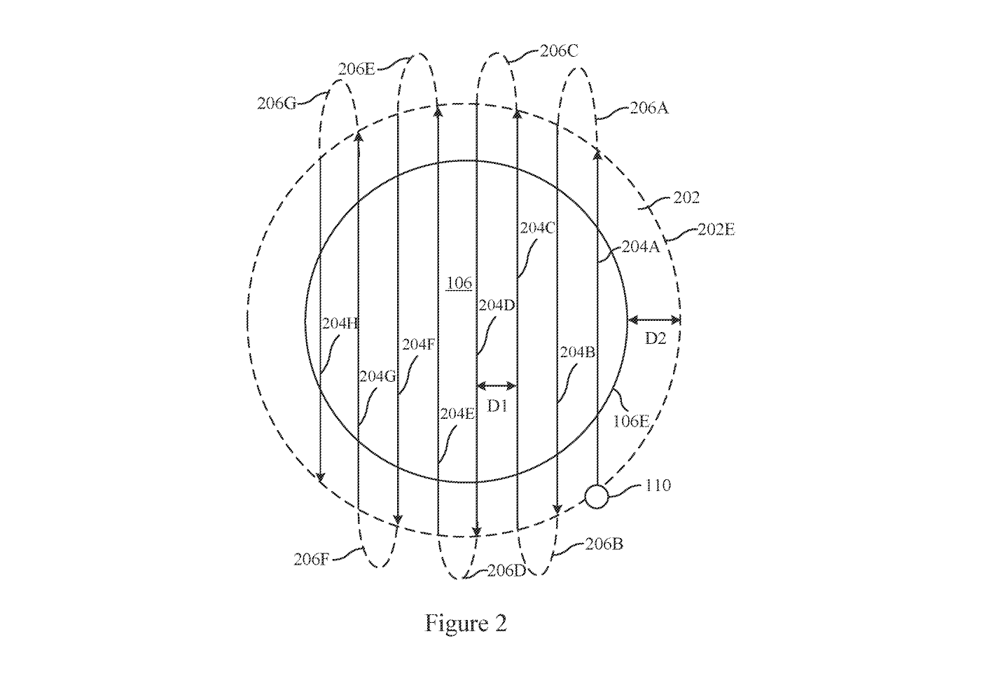

FIG. 2 is a schematic view of a particle beam process in accordance with various embodiments. FIG. 2 is described in conjunction with FIG. 1. In the illustrated embodiment, the particle beam process is an etch process. In other embodiments, the particle beam process may be an oxidation process, a nitridation process, or the like. In some embodiments, the controller 116 may determine a plurality of paths 204A-204H on a surface of the wafer 106. As described below in greater detail, the particle beam 110 follows the plurality of paths 204A-204H while scanning the surface of the wafer 106 to partially or completely cover the wafer 106. In some embodiments, the plurality of paths 204A-204H may be parallel straight paths with adjacent paths separated by a distance D₁. The distance D₁ may be in a range from 0.5 mm to 5 mm. In some embodiments, the particle beam 110 may move in opposite directions while following adjacent paths. In the illustrated embodiment, the particle beam 110 moves in a first direction along the paths 204A, 204C, 204E, and 204G, and in a second direction along the paths 204B, 204D, 204F, and 204H, with the second direction being opposite to the first direction.

In some embodiments, the controller 116 may further determine an overscan region 202 for the wafer 106. The overscan region 202 may extend beyond an edge 106E of the wafer 106 by a distance D₂, allowing for consistent treatment up to and including the periphery of the wafer 106. The distance D₂ may be in a range from 5 mm to 20 mm.

The controller 116 may further set a desired etch rate of the particle beam 110. In some embodiments, the etch rate of the particle beam 110 may be altered by changing a scanning speed of the chuck 104. The scanning speed dictates how quickly the particle beam 110 moves across the wafer 106. The etch rate of the particle beam 110 decreases as the scanning speed increases, such that a minimal value of the etch rate corresponds to a maximal value of the scanning speed.

In other embodiments, the etch rate of the particle beam 110 may be altered by changing a duty cycle of the particle beam 110. The duty cycle controls when the particle beam 110 delivers particles to the surface of the wafer 106. The etch rate of the particle beam 110 decreases as the duty cycle of the particle beam 110 decreases. The duty cycle may be measured in percentages and may be in a range from 0% to 100%. For example, the duty cycle of X% corresponds to the particle beam 110 having on-state for X% of the total beam time and off-state for (100-X)% of the total beam time. In some embodiments, when the particle beam 110 is a pulsed beam having a period T, the duty cycle may be determined as (T_{ON}/T)*100%, wherein T_{ON} is the on-state duration within the period T. In some embodiments, when the particle beam 110 is the pulsed beam, a pulse frequency of the particle beam 110 may be in a range from 100 Hz to 10 kHz.

In some embodiments, to set an etch rate of the particle beam 110 to the desired etch rate, the controller 116 may determine a scanning speed of the chuck 104 and/or a duty cycle of the particle beam 110. Subsequently, the controller 116 may send a signal 124 to the particle beam apparatus 100, with the signal 124 instructing the particle beam apparatus 100 to set a scanning speed of the chuck 104 and/or a duty cycle of the particle beam 110 to the determined scanning speed and/or the determined duty cycle.

After setting the etch rate, the controller 116 may send a signal 124 to the particle beam apparatus 100 to start a scanning process along a first path (e.g., path 204A). In some embodiments, as the particle beam 110 traverses the first path (e.g., path 204A), scanning speed and/or duty cycle may be dynamically altered according to the desired etch rate of the particle beam 110. This adaptability allows for fine-tuning of characteristics of the particle beam 110 in response to varying wafer conditions or specific process requirements.

In some embodiments, throughout this scanning process, a location of the particle beam 110 along the first path (e.g., path 204A) may be continuously monitored by the controller 116. When the particle beam 110 beam reaches an outer edge 202E of the overscan region 202, the controller 116 may send a signal 124 to the particle beam apparatus 100 to turn on a reduced trim mode with a reduced etch rate. In some embodiments, the signal 124 may further instruct the particle beam apparatus 100 to set a scanning speed of the chuck 104 and/or duty cycle of the particle beam 110 to a determined scanning speed and/or determined duty cycle that correspond to a desired reduced etch rate.

In some embodiments, after turning on the reduced trim mode, the controller 116 may send a signal 124 to the particle beam apparatus 100 to decelerate the chuck 104 for a deceleration time until the scanning speed reaches zero, change the direction of the chuck 104 to the opposite direction, and accelerate the chuck 104 for an acceleration time until the particle beam 110 reaches the outer edge 202E of the overscan region 202 with a desired scanning speed. Subsequently, the controller 116 may send a signal 124 to the particle beam apparatus 100 to turn off the reduced trim mode. In some embodiments, the particle beam apparatus 100 follows a path 206A during the reduced trim mode. By reducing the etch rate during the reduced trim mode, unintended etch (e.g., overetch) near the edge 106E of the wafer 106 may be reduced. In some embodiments, the deceleration time may be the same as the acceleration time. In other embodiments, the deceleration time may be different from the acceleration time. The deceleration time may be in a range from 20 ms to 200 ms. The acceleration time may be in a range from 20 ms to 200 ms.

In some embodiments, the signal 124 that instructs the particle beam apparatus 100 to turn on the reduced trim mode may instruct the particle beam apparatus 100 to reduce the etch rate of the particle beam 110 to zero. For example, the signal 124 may instruct the particle beam apparatus 100 to set the duty cycle of the particle beam 110 to 0%, which corresponds to turning off the energized particle beam 110. In such embodiments, the reduced trim mode may be also referred to as a zero trim mode.

In some embodiments, the above-described process may be repeated for each subsequent path (e.g., paths 204B-204H) on the surface of the wafer 106. Before each new path is scanned, the scanning speed of the chuck 104 and/or the duty cycle of the particle beam 110 may be reset to values desired for that specific path. As with the first path 204A, these parameters may be altered during scanning to adapt to changing conditions or requirements. The location of the particle beam 110 may be continuously monitored and the reduced trim mode may be turned on each time the particle beam 110 reaches the edge 202E of the overscan region 202. During each reduced trim mode, the particle beam 110 may follow a respective path (e.g., respective one of paths 206B-206G). The scanning process may continue until all paths 204A-204H on the surface of the wafer 106 have been scanned.

Various embodiments of the disclosed apparatus and method ensure that the entire wafer 106 receives controlled particle beam treatment, with the flexibility to adjust beam parameters (such as scanning speed, duty cycle, pulse frequency, and etch rate) for each path and during scanning. The management of the particle beam 110 at the outer edge 202E of the overscan region 202 may prevent overexposure (e.g., overetch) at the edge 106E of the wafer 106 and allow for seamless transitions between paths. This approach may result in uniform and accurate particle beam treatment across the entire wafer surface that is desired for many advanced manufacturing processes. Furthermore, by using the reduced trim mode, the area of the overscan region 202 may be reduced, lifetime of parts of the particle beam apparatus 100 that would be otherwise exposed to the particle beam 110 in the overscan region 202 may be improved, and amount of particles generated by to the particle beam 110 may be reduced. By reducing the area of the overscan region 202, time spent by the particle beam 110 in the overscan region 202 may be reduced and a wafer-per-hour yield of the particle beam apparatus 100 may be improved.

FIGS. 3A-3C illustrate a flow diagram of a particle beam method 300 in accordance with various embodiments. The method 300 is described in conjunction with FIGS. 1 and 2. The method 300 may be implemented, at least in part, in the form of executable code (e.g., software instructions 122 of FIG. 1) stored on non-transitory, tangible, computer-readable medium (e.g., memory 120 of FIG. 1) that when executed by one or more processors (e.g., processor 118 of FIG. 1) may cause the one or more processors to perform one or more of the steps 302-342. In some embodiments, the particle beam method 300 may be an etch method. Although shown in a particular sequence, it should be appreciated that the steps of method 300 may be performed in any suitable sequence.

Method 300 starts with step 302. In step 302, a processor (e.g., processor 118 of FIG. 1) of a controller (e.g., controller 116 of FIG. 1) of a particle beam apparatus (e.g., particle beam apparatus 100 of FIG. 1) determines a plurality of paths (e.g., paths 204A-204H of FIG. 2) on a surface of a wafer (e.g., wafer 106 of FIGS. 1 and 2). In step 304, the processor (e.g., processor 118 of FIG. 1) of the controller (e.g., controller 116 of FIG. 1) of the particle beam apparatus (e.g., particle beam apparatus 100 of FIG. 1) determines an overscan region (e.g., overscan region 202 of FIG. 1) for the wafer (e.g., wafer 106 of FIGS. 1 and 2).

Subsequently, the processor (e.g., processor 118 of FIG. 1) of the controller (e.g., controller 116 of FIG. 1) of the particle beam apparatus (e.g., particle beam apparatus 100 of FIG. 1) sets a desired etch rate of a particle beam (e.g., particle beam 110 of FIGS. 1 and 2). In some embodiments, the setting process may comprise one or both of steps 306 and 308.

In step 306, the processor (e.g., processor 118 of FIG. 1) of the controller (e.g., controller 116 of FIG. 1) of the particle beam apparatus (e.g., particle beam apparatus 100 of FIG. 1) sets a scanning speed of the wafer (e.g., wafer 106 of FIGS. 1 and 2). In one embodiment, the scanning speed is a speed of a chuck (e.g., chuck 104 of FIG. 1) while the particle beam (e.g., particle beam 110 of FIGS. 1 and 2) remains static.

In some embodiments, the processor (e.g., processor 118 of FIG. 1) of the controller (e.g., controller 116 of FIG. 1) of the particle beam apparatus (e.g., particle beam apparatus 100 of FIG. 1) determines a desired scanning speed. Subsequently, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to set the scanning speed to the desired scanning speed.

In step 308, the processor (e.g., processor 118 of FIG. 1) of the controller (e.g., controller 116 of FIG. 1) of the particle beam apparatus (e.g., particle beam apparatus 100 of FIG. 1) sets a duty cycle of the particle beam (e.g., particle beam 110 of FIGS. 1 and 2). In some embodiments, the processor (e.g., processor 118 of FIG. 1) of the controller (e.g., controller 116 of FIG. 1) of the particle beam apparatus (e.g., particle beam apparatus 100 of FIG. 1) determines a desired duty cycle of the particle beam (e.g., particle beam 110 of FIGS. 1 and 2). Subsequently, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to set the duty cycle of the particle beam (e.g., particle beam 110 of FIGS. 1 and 2) to the desired duty cycle.

In step 310, the processor (e.g., processor 118 of FIG. 1) of the controller (e.g., controller 116 of FIG. 1) of the particle beam apparatus (e.g., particle beam apparatus 100 of FIG. 1) starts scanning the particle beam (e.g., particle beam 110 of FIGS. 1 and 2) along a first path (e.g., path 204A of FIG. 2). In some embodiments, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to start scanning the particle beam (e.g., particle beam 110 of FIGS. 1 and 2) along the first path (e.g., path 204A of FIG. 2).

In some embodiments, as the particle beam (e.g., particle beam 110 of FIGS. 1 and 2) traverses the first path (e.g., path 204A of FIG. 2), its etch rate may be dynamically altered according to the desired etch rate of the particle beam (e.g., particle beam 110 of FIGS. 1 and 2). In some embodiments, the etch rate altering process may comprise one or both of steps 312 and 314. In other embodiments, the etch rate altering process may be omitted.

In step 312, the processor (e.g., processor 118 of FIG. 1) of the controller (e.g., controller 116 of FIG. 1) of the particle beam apparatus (e.g., particle beam apparatus 100 of FIG. 1) alters the scanning speed of the wafer (e.g., wafer 106 of FIGS. 1 and 2). In some embodiments, the processor (e.g., processor 118 of FIG. 1) of the controller (e.g., controller 116 of FIG. 1) of the particle beam apparatus (e.g., particle beam apparatus 100 of FIG. 1) determines a desired scanning speed. Subsequently, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to set the scanning speed of the wafer (e.g., wafer 106 of FIGS. 1 and 2) to the desired scanning speed.

In step 314, the processor (e.g., processor 118 of FIG. 1) of the controller (e.g., controller 116 of FIG. 1) of the particle beam apparatus (e.g., particle beam apparatus 100 of FIG. 1) alters the duty cycle of the particle beam (e.g., particle beam 110 of FIGS. 1 and 2). In some embodiments, the processor (e.g., processor 118 of FIG. 1) of the controller (e.g., controller 116 of FIG. 1) of the particle beam apparatus (e.g., particle beam apparatus 100 of FIG. 1) determines a desired duty cycle of the particle beam (e.g., particle beam 110 of FIGS. 1 and 2). Subsequently, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to set the duty cycle of the particle beam (e.g., particle beam 110 of FIGS. 1 and 2) to the desired duty cycle.

In step 316, the processor (e.g., processor 118 of FIG. 1) of the controller (e.g., controller 116 of FIG. 1) of the particle beam apparatus (e.g., particle beam apparatus 100 of FIG. 1) determines a location of the particle beam (e.g., particle beam 110 of FIGS. 1 and 2) along the first path (e.g., path 204A of FIG. 2). In step 318, the processor (e.g., processor 118 of FIG. 1) of the controller (e.g., controller 116 of FIG. 1) of the particle beam apparatus (e.g., particle beam apparatus 100 of FIG. 1) determines whether the particle beam (e.g., particle beam 110 of FIGS. 1 and 2) is located at an outer edge (e.g., edge 202E of FIG. 2) of the overscan region (e.g., overscan region 202 of FIG. 2).

In response to determining at step 318 that the particle beam (e.g., particle beam 110 of FIGS. 1 and 2) is not located at the outer edge (e.g., edge 202E of FIG. 2) of the overscan region (e.g., overscan region 202 of FIG. 2), method 300 proceeds to step 316. In some embodiments, steps 316 and 318 may be repeated one or more times until the particle beam (e.g., particle beam 110 of FIGS. 1 and 2) is located at the outer edge (e.g., edge 202E of FIG. 2) of the overscan region (e.g., overscan region 202 of FIG. 2).

In response to determining at step 318 that the particle beam (e.g., particle beam 110 of FIGS. 1 and 2) is located at the outer edge (e.g., edge 202E of FIG. 2) of the overscan region (e.g., overscan region 202 of FIG. 2), method 300 proceeds to step 320. In step 320, the processor (e.g., processor 118 of FIG. 1) of the controller (e.g., controller 116 of FIG. 1) of the particle beam apparatus (e.g., particle beam apparatus 100 of FIG. 1) turns on a reduced trim mode with a reduced etch rate. In some embodiments, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1) to turn on the reduced trim mode.

In some embodiments, the signal (e.g., signal 124 of FIG. 1) may further instruct the particle beam apparatus (e.g., particle beam apparatus 100 of FIG. 1) to set a scanning speed and/or a duty cycle of the particle beam (e.g., particle beam 110 of FIGS. 1 and 2) to a determined scanning speed and/or a determined duty cycle that correspond to the desired reduced etch rate. In other embodiments, the signal (e.g., signal 124 of FIG. 1) may further instruct the particle beam apparatus (e.g., particle beam apparatus 100 of FIG. 1) to reduce the etch rate of the particle beam (e.g., particle beam 110 of FIGS. 1 and 2) to zero. For example, the signal (e.g., signal 124 of FIG. 1) may instruct the particle beam apparatus (e.g., particle beam apparatus 100 of FIG. 1) to set the duty cycle of the particle beam (e.g., particle beam 110 of FIGS. 1 and 2) to 0%, which corresponds to turning off the particle beam (e.g., particle beam 110 of FIGS. 1 and 2). In such embodiments, the reduced trim mode may be also referred to as a zero trim mode.

In step 322, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1) to decelerate the wafer (e.g., wafer 106 of FIGS. 1 and 2) for a first time until the scanning speed reaches zero.

In step 324, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1) to change the direction of the wafer (e.g., wafer 106 of FIGS. 1 and 2) to the opposite direction, and accelerate the wafer (e.g., wafer 106 of FIGS. 1 and 2) for a second time until the particle beam (e.g., particle beam 110 of FIGS. 1 and 2) reaches the outer edge (e.g., edge 202E of FIG. 2) of the overscan region (e.g., overscan region 202 of FIG. 2). In some embodiments, the first time may be the same as the second time. In other embodiments, the first time may be different from the second time.

In step 326, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1) to turn off the reduced trim mode. In some embodiments when the reduced trim mode is the zero trim mode, the signal (e.g., signal 124 of FIG. 1) may instruct the particle beam apparatus (e.g., particle beam apparatus 100 of FIG. 1) to turn on the particle beam (e.g., particle beam 110 of FIGS. 1 and 2).

Subsequently, the processor (e.g., processor 118 of FIG. 1) of the controller (e.g., controller 116 of FIG. 1) of the particle beam apparatus (e.g., particle beam apparatus 100 of FIG. 1) sets a desired etch rate of the particle beam (e.g., particle beam 110 of FIGS. 1 and 2). In some embodiments, the setting process may comprise one or both of steps 328 and 330.

In step 328, the processor (e.g., processor 118 of FIG. 1) of the controller (e.g., controller 116 of FIG. 1) of the particle beam apparatus (e.g., particle beam apparatus 100 of FIG. 1) sets a scanning speed of the wafer (e.g., wafer 106 of FIGS. 1 and 2). In some embodiments, the processor (e.g., processor 118 of FIG. 1) of the controller (e.g., controller 116 of FIG. 1) of the particle beam apparatus (e.g., particle beam apparatus 100 of FIG. 1) determines a desired scanning speed. Subsequently, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to set the scanning speed of the wafer (e.g., wafer 106 of FIGS. 1 and 2) to the desired scanning speed.

In step 330, the processor (e.g., processor 118 of FIG. 1) of the controller (e.g., controller 116 of FIG. 1) of the particle beam apparatus (e.g., particle beam apparatus 100 of FIG. 1) sets a duty cycle of the particle beam (e.g., particle beam 110 of FIGS. 1 and 2). In some embodiments, the processor (e.g., processor 118 of FIG. 1) of the controller (e.g., controller 116 of FIG. 1) of the particle beam apparatus (e.g., particle beam apparatus 100 of FIG. 1) determines a desired duty cycle of the particle beam (e.g., particle beam 110 of FIGS. 1 and 2). Subsequently, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to set the duty cycle of the particle beam (e.g., particle beam 110 of FIGS. 1 and 2) to the desired duty cycle.

In step 332, the processor (e.g., processor 118 of FIG. 1) of the controller (e.g., controller 116 of FIG. 1) of the particle beam apparatus (e.g., particle beam apparatus 100 of FIG. 1) starts scanning the particle beam (e.g., particle beam 110 of FIGS. 1 and 2) along a next path (e.g., path 204B of FIG. 2). In some embodiments, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to starts scanning the particle beam (e.g., particle beam 110 of FIGS. 1 and 2) along the next path (e.g., path 204B of FIG. 2).

In some embodiments, as the particle beam (e.g., particle beam 110 of FIGS. 1 and 2) traverses the next path (e.g., path 204B of FIG. 2), its etch rate may be dynamically altered according to the desired etch rate of the particle beam (e.g., particle beam 110 of FIGS. 1 and 2). In some embodiments, the etch rate altering process may comprise one or both of steps 334 and 336. In other embodiments, the etch rate altering process may be omitted.

In step 334, the processor (e.g., processor 118 of FIG. 1) of the controller (e.g., controller 116 of FIG. 1) of the particle beam apparatus (e.g., particle beam apparatus 100 of FIG. 1) alters the scanning speed of the wafer (e.g., wafer 106 of FIGS. 1 and 2). In some embodiments, the processor (e.g., processor 118 of FIG. 1) of the controller (e.g., controller 116 of FIG. 1) of the particle beam apparatus (e.g., particle beam apparatus 100 of FIG. 1) determines a desired scanning speed. Subsequently, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to set the scanning speed of the wafer (e.g., wafer 106 of FIGS. 1 and 2) to the desired scanning speed.

In step 336, the processor (e.g., processor 118 of FIG. 1) of the controller (e.g., controller 116 of FIG. 1) of the particle beam apparatus (e.g., particle beam apparatus 100 of FIG. 1) alters the duty cycle of the particle beam (e.g., particle beam 110 of FIGS. 1 and 2). In some embodiments, the processor (e.g., processor 118 of FIG. 1) of the controller (e.g., controller 116 of FIG. 1) of the particle beam apparatus (e.g., particle beam apparatus 100 of FIG. 1) determines a desired duty cycle of the particle beam (e.g., particle beam 110 of FIGS. 1 and 2). Subsequently, the processor (e.g., processor 118 of FIG. 1) of the controller (e.g., controller 116 of FIG. 1) of the particle beam apparatus (e.g., particle beam apparatus 100 of FIG. 1) may send a signal (e.g., signal 124 of FIG. 1) to the particle beam apparatus (e.g., particle beam apparatus 100 of FIG. 1), with the signal (e.g., signal 124 of FIG. 1) instructing the particle beam apparatus (e.g., particle beam apparatus 100 of FIG. 1) to set the duty cycle of the particle beam (e.g., particle beam 110 of FIGS. 1 and 2) to the desired duty cycle.

In step 338, the processor (e.g., processor 118 of FIG. 1) of the controller (e.g., controller 116 of FIG. 1) of the particle beam apparatus (e.g., particle beam apparatus 100 of FIG. 1) determines a location of the particle beam (e.g., particle beam 110 of FIGS. 1 and 2) along the next path (e.g., path 204B of FIG. 2). In step 340, the processor (e.g., processor 118 of FIG. 1) of the controller (e.g., controller 116 of FIG. 1) of the particle beam apparatus (e.g., particle beam apparatus 100 of FIG. 1) determines whether the particle beam (e.g., particle beam 110 of FIGS. 1 and 2) is located at an outer edge (e.g., edge 202E of FIG. 2) of the overscan region (e.g., overscan region 202 of FIG. 2).

In response to determining at step 340 that the particle beam (e.g., particle beam 110 of FIGS. 1 and 2) is not located at the outer edge (e.g., edge 202E of FIG. 2) of the overscan region (e.g., overscan region 202 of FIG. 2), method 300 proceeds to step 338. In some embodiments, steps 338 and 340 may be repeated one or more times until the particle beam (e.g., particle beam 110 of FIGS. 1 and 2) is located at the outer edge (e.g., edge 202E of FIG. 2) of the overscan region (e.g., overscan region 202 of FIG. 2).

In response to determining at step 340 that the particle beam (e.g., particle beam 110 of FIGS. 1 and 2) is located at the outer edge (e.g., edge 202E of FIG. 2) of the overscan region (e.g., overscan region 202 of FIG. 2), method 300 proceeds to step 342. In step 342, the processor (e.g., processor 118 of FIG. 1) of the controller (e.g., controller 116 of FIG. 1) of the particle beam apparatus (e.g., particle beam apparatus 100 of FIG. 1) determines whether all paths (e.g., paths 204A-204H) are scanned.

In response to determining at step 342 that all paths (e.g., paths 204A-204H) are not scanned, method 300 proceeds to step 320. In some embodiments, steps 302 through 342 may be repeated one or more times until all paths (e.g., paths 204A-204H) are scanned. In response to determining at step 342 that all paths (e.g., paths 204A-204H) are scanned, method 300 proceeds to end.

Example embodiments of the disclosure are described below. Other embodiments can also be understood from the entirety of the specification as well as the claims filed herein.

Example 1. An apparatus including: a process chamber configured to hold a wafer; a nozzle within the process chamber, where the nozzle is configured to provide a particle beam impacting the wafer; and a controller operably coupled to the process chamber, where the controller is configured to: determine a plurality of paths on a surface of the wafer; determine an overscan region for the wafer; (a) set an etch rate of the particle beam; (b) scan the particle beam along a first path of the plurality of paths; (c) monitor a location of the particle beam along the first path; (d) in response to determining that the particle beam is located at an outer edge of the overscan region: turn on a reduced trim mode, where turning on the reduced trim mode comprises reducing the etch rate of the particle beam; decelerate the wafer to zero scanning speed; accelerate the wafer until the particle beam is located at an outer edge of the overscan region; and turn off the reduced trim mode; and repeat (a)-(d) for each subsequent path of the plurality of paths until all paths have been scanned.

Example 2. The apparatus of example 1, where turning on the reduced trim mode includes turning off the particle beam.

Example 3. The apparatus of one of examples 1 and 2, where turning off the reduced trim mode includes turning on the particle beam.

Example 4. The apparatus of one of examples 1 to 3, where setting the etch rate of the particle beam includes setting a scanning speed of the wafer.

Example 5. The apparatus of one of examples 1 to 4, where setting the etch rate of the particle beam includes setting a duty cycle of the particle beam.

Example 6. The apparatus of one of examples 1 to 5, where reducing the etch rate of the particle beam includes reducing a duty cycle of the particle beam.

Example 7. The apparatus of one of examples 1 to 6, where turning on the reduced trim mode includes reducing the etch rate of the particle beam to zero.

Example 8. A device operably coupled to a process chamber of a particle beam apparatus, the device including: a processor; a non-transitory computer-readable medium storing software instructions that, when executed by the processor, causes the processor to: determine a plurality of paths on a surface of a wafer; determine an overscan region for the wafer; (a) set an etch rate of a particle beam; (b) scan the particle beam along a first path of the plurality of paths; (c) monitor a location of the particle beam along the first path; (d) in response to determining that the particle beam is located at an outer edge of the overscan region: turn on a reduced trim mode, where turning on the reduced trim mode comprises reducing the etch rate of the particle beam; decelerate the wafer to zero scanning speed; accelerate the wafer until the particle beam is located at an outer edge of the overscan region; and turn off the reduced trim mode; and repeat (a)-(d) for each subsequent path of the plurality of paths until all paths have been scanned.

The device of example 8, where turning on the reduced trim mode includes turning off the particle beam.

The device of one of examples 8 and 9, where turning off the reduced trim mode includes turning on the particle beam.

The device of one of examples 8 to 10, where setting the etch rate of the particle beam includes setting a scanning speed of the wafer.

The device of one of examples 8 to 11, where setting the etch rate of the particle beam includes setting a duty cycle of the particle beam.

The device of one of examples 8 to 12, where reducing the etch rate of the particle beam includes reducing a duty cycle of the particle beam.

The device of one of examples 8 to 13, where turning on the reduced trim mode includes reducing the etch rate of the particle beam to zero.

A method including: determining a plurality of paths on a surface of a wafer; determining an overscan region for the wafer; (a) setting an etch rate of a particle beam; (b) scanning the particle beam along a first path of the plurality of paths; (c) monitoring a location of the particle beam along the first path; (d) in response to determining that the particle beam is located at an outer edge of the overscan region: turning on a reduced trim mode, where turning on the reduced trim mode comprises reducing the etch rate of the particle beam; decelerating the wafer to zero scanning speed; accelerating the wafer until the particle beam is located at an outer edge of the overscan region; and turning off the reduced trim mode; and repeating (a)-(d) for each subsequent path of the plurality of paths until all paths have been scanned.

The method of example 15, where turning on the reduced trim mode includes turning off the particle beam.

The method of one of examples 15 and 16, where turning off the reduced trim mode includes turning on the particle beam.

The method of one of examples 15 to 17, where setting the etch rate of the particle beam includes setting a scanning speed of the wafer.

The method of one of examples 15 to 18, where setting the etch rate of the particle beam includes setting a duty cycle of the particle beam.

The method of one of examples 15 to 19, where reducing the etch rate of the particle beam includes reducing a duty cycle of the particle beam.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. An apparatus comprising:
a process chamber configured to hold a wafer;
a nozzle within the process chamber, wherein the nozzle is configured to provide a particle beam impacting the wafer; and
a controller operably coupled to the process chamber, wherein the controller is configured to:
determine a plurality of paths on a surface of the wafer;
determine an overscan region for the wafer;
(a) set an etch rate of the particle beam;
(b) scan the particle beam along a first path of the plurality of paths;
(c) monitor a location of the particle beam along the first path;
(d) in response to determining that the particle beam is located at an outer edge of the overscan region:
turn on a reduced trim mode, wherein turning on the reduced trim mode comprises reducing the etch rate of the particle beam;
decelerate the wafer to zero scanning speed;
accelerate the wafer until the particle beam is located at an outer edge of the overscan region; and
turn off the reduced trim mode; and
repeat (a)-(d) for each subsequent path of the plurality of paths until all paths have been scanned.

2. The apparatus of claim 1, wherein turning on the reduced trim mode comprises turning off the particle beam.

3. The apparatus of claim 1, wherein turning off the reduced trim mode comprises turning on the particle beam.

4. The apparatus of claim 1, wherein setting the etch rate of the particle beam comprises setting a scanning speed of the wafer.

5. The apparatus of claim 1, wherein setting the etch rate of the particle beam comprises setting a duty cycle of the particle beam.

6. The apparatus of claim 1, wherein reducing the etch rate of the particle beam comprises reducing a duty cycle of the particle beam.

7. The apparatus of claim 1, wherein turning on the reduced trim mode comprises reducing the etch rate of the particle beam to zero.

8. A device operably coupled to a process chamber of a particle beam apparatus, the device comprising:
a processor;
a non-transitory computer-readable medium storing software instructions that, when executed by the processor, causes the processor to:
determine a plurality of paths on a surface of a wafer;
determine an overscan region for the wafer;
(a) set an etch rate of a particle beam;
(b) scan the particle beam along a first path of the plurality of paths;
(c) monitor a location of the particle beam along the first path;
(d) in response to determining that the particle beam is located at an outer edge of the overscan region:
turn on a reduced trim mode, wherein turning on the reduced trim mode comprises reducing the etch rate of the particle beam;
decelerate the wafer to zero scanning speed;
accelerate the wafer until the particle beam is located at an outer edge of the overscan region; and
turn off the reduced trim mode; and
repeat (a)-(d) for each subsequent path of the plurality of paths until all paths have been scanned.

9. The device of claim 8, wherein turning on the reduced trim mode comprises turning off the particle beam.

10. The device of claim 8, wherein turning off the reduced trim mode comprises turning on the particle beam.

11. The device of claim 8, wherein setting the etch rate of the particle beam comprises setting a scanning speed of the wafer.

12. The device of claim 8, wherein setting the etch rate of the particle beam comprises setting a duty cycle of the particle beam.

13. The device of claim 8, wherein reducing the etch rate of the particle beam comprises reducing a duty cycle of the particle beam.

14. The device of claim 8, wherein turning on the reduced trim mode comprises reducing the etch rate of the particle beam to zero.

15. A method comprising:
determining a plurality of paths on a surface of a wafer;
determining an overscan region for the wafer;
(a) setting an etch rate of a particle beam;
(b) scanning the particle beam along a first path of the plurality of paths;
(c) monitoring a location of the particle beam along the first path;
(d) in response to determining that the particle beam is located at an outer edge of the overscan region:
turning on a reduced trim mode, wherein turning on the reduced trim mode comprises reducing the etch rate of the particle beam;
decelerating the wafer to zero scanning speed;
accelerating the wafer until the particle beam is located at an outer edge of the overscan region; and
turning off the reduced trim mode; and
repeating (a)-(d) for each subsequent path of the plurality of paths until all paths have been scanned.

16. The method of claim 15, wherein turning on the reduced trim mode comprises turning off the particle beam.

17. The method of claim 15, wherein turning off the reduced trim mode comprises turning on the particle beam.

18. The method of claim 15, wherein setting the etch rate of the particle beam comprises setting a scanning speed of the wafer.

19. The method of claim 15, wherein setting the etch rate of the particle beam comprises setting a duty cycle of the particle beam.

20. The method of claim 15, wherein reducing the etch rate of the particle beam comprises reducing a duty cycle of the particle beam.
